(19) United States
(12) Patent Application Publication
(10) Pub. No.: US 2025/0123562 A1
(43) Pub. Date: Apr. 17, 2025

(54) PHOTORESIST MATERIAL AND METHOD FOR LITHOGRAPHY

(71) Applicant: Taiwan Semiconductor Manufacturing Company LTD, Hsinchu (TW)

(72) Inventors: Ming-Hui Weng, New Taipei (TW); Wei-Han Lai, New Taipei (TW); Ching-Yu Chang, Yuansun (TW)

(21) Appl. No.: 18/379,870

(22) Filed: Oct. 13, 2023

(51) Int. Cl. G03F 7/039; G03F 7/038

(52) U.S. Cl. CPC G03F 7/039; G03F 7/038

(57) ABSTRACT

A photoresist composition comprises an organic polymer and a floatable polymer. The floatable polymer has a lower surface energy than the organic polymer. Upon curing, the floatable polymer forms a surface layer above the photoresist layer formed by the organic polymer. The presence of the surface layer reduces optical flare and chemical flare, thus improving the critical dimension of the features formed in a material layer below the photoresist layer.

### BACKGROUND

Integrated circuits are formed on a semiconductor wafer. Photolithographic patterning processes use ultraviolet light to transfer a mask pattern to a photoresist on a semiconductor wafer. Etching processes may then be used to transfer to the pattern to a layer below the photoresist. This process is repeated multiple times with different patterns to build different layers on the wafer substrate and make a useful device.

High-resolution lithography processes are needed to obtain smaller feature sizes. An example of one such process is extreme ultraviolet (EUV) lithography, which uses wavelengths of about 10 nanometers (nm) to about 100 nm. Further improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method for preparing a patterned photoresist layer and etching a layer of a semiconducting device, in accordance with some embodiments.

FIG. 2A is a cross-sectional view of a substrate prior to starting the method of FIG. 1.

FIG. 2B is a cross-sectional view of a substrate with a first material layer located upon the substrate, again prior to starting the method of FIG. 1.

FIG. 2C is a cross-sectional view of a substrate with two underlayers applied upon the first material layer, again prior to starting the method of FIG. 1.

FIG. 3 is a cross-sectional view of the substrate with a photoresist layer over the first material layer, and a surface layer over the photoresist layer.

FIG. 4 is a cross-sectional view of the substrate after radiation exposure, with the photoresist layer now including soluble regions and insoluble regions.

FIG. 5 is a cross-sectional view of the substrate after development, with a patterned photoresist layer.

FIG. 6 is a cross-sectional view of the final structure with a patterned first material layer.

FIG. 7 is an illustration showing the effect of the surface layer formed from the floatable polymer on subsequent photoresist patterning.

FIG. 8 is an illustration of an extreme ultraviolet (EUV) photolithography system for exposing the photoresist layer to EUV radiation, in accordance with some embodiments.

FIG. 9 is an image of an experimental example which did not use floatable polymer in the photoresist composition.

FIG. 10 is an image of an experimental example which contained floatable polymer in the photoresist composition.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure may refer to temperatures for certain method steps. It is noted that these references are to the temperature at which the heat source is set, and do not specifically refer to the temperature which must be attained by a particular material being exposed to the heat.

The term “ambient temperature” or “room temperature” refers to a temperature of 15° C. to 30° C.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

As used herein, the term “copolymer” refers to a polymeric molecule derived from two or more monomers, as opposed to a homopolymer, which is a molecule derived from only one monomer. The term “dipolymer” refers to a molecule derived from only two different monomers. The term “terpolymer” refers to a molecule derived from only three different monomers. The term “tetrapolymer” refers to a molecule derived from only four different monomers.

The terms “monomer” and “repeating unit” are used interchangeably in the text. A repeating unit is derived from a monomer, and they differ in a known manner in their structure.

The term “alkyl” refers to a radical composed entirely of carbon atoms and hydrogen atoms which is fully saturated (i.e. does not contain double or triple bonds). The alkyl radical may be linear, branched, or cyclic. The alkyl radical may bond to one or two other atoms, depending on the context in which it is used. For example, both methyl (—CH₃) and methylene (—CH₂—) should be considered alkyl radicals. As used herein, an alkyl radical may contain 1 to 8 carbon atoms.

The term “aryl” refers to an aromatic radical composed entirely of carbon atoms, and optionally hydrogen atoms along the perimeter of the radical. As used herein, an aryl group may have from 6 to about 18 carbon atoms. The term “aryl” should not be construed as including substituted aromatic radicals, such as methylphenyl group (7 carbon atoms). The aromatic radical may bond to one or two other atoms, depending on the context in which it is used. For example, both phenyl (—C₆H₅) and phenylene (—C₆H₄—) should be considered aromatic radicals.

The term “heteroaryl” refers to a cyclic radical composed of carbon atoms, hydrogen atoms, and a heteroatom within a ring of the radical, the cyclic radical being aromatic. The heteroatom may be nitrogen, sulfur, or oxygen. Exemplary heteroaryl groups include thienyl, pyridinyl, furanyl, pyrryl, indolyl, and quinolinyl. When heteroaryl is described in connection with a numerical range of carbon atoms, it should not be construed as including substituted heteroaromatic radicals. The heteroaryl radical has the ability to form a single bond to one or two different non-hydrogen atoms, depending on the context. For example, the radicals —C₄H₃S and —C₄H₂S— could both be referred to as thienyl, and should both be considered heteroaryl radicals. As used herein, a heteroaryl group has from 5 to about 18 carbon atoms.

The term “ester” refers to a radical of the formula —CO—O—.

The term “carboxyl” refers to a radical of the formula —CO—OR″, where R″ is hydrogen or alkyl, and also refers to the salt thereof. The carboxy radical bonds through the carbon atom. It is noted that a carbonate group (—O—CO—OR″) should not be considered a carboxyl group.

The term “hydroxyl” refers to the —OH radical.

The term “amino” refers to a radical of the formula —NR¹R², where R¹ and R² are independently hydrogen or alkyl. This includes monosubstituted radicals (i.e. where R² is hydrogen) and disubstituted radicals (where neither R¹ nor R² are hydrogen). When R¹ and R² are alkyl, the alkyl chains may be substituted with fluorine atoms.

The term “alkoxy” refers to an alkyl radical which is attached to an oxygen atom, i.e. —O—CₙH₂ₙ₊₁.

The term “alkylthio” refers to an alkyl radical which is attached to a sulfur atom, i.e. —S—CₙH₂ₙ₊₁.

The term “sulfhydryl” refers to the —SH radical.

The term “acylamido” refers to a radical of the formula —N(R¹)—CO—R², where R¹ and R² are independently hydrogen, alkyl, substituted alkyl, aryl, or substituted aryl. The acylamido radical bonds through the nitrogen atom.

The term “acyloxy” refers to a radical of the formula —O—CO—R, where R is hydrogen, alkyl, substituted alkyl, aryl, or substituted aryl, and also refers to the salt thereof. The acyloxy radical bonds through an oxygen atom.

The term “nitro” refers to a radical of the formula —NO₂.

The term “cyano” refers to a radical of the formula —CN.

The term “halogen” refers to a fluorine (F), chlorine (Cl), bromine (Br), or iodine (I) atom.

The term “nitroso” refers to a radical of the formula —N═O.

The term “acyl” refers to a radical of the formula —CO—R, where R is hydrogen, alkyl, substituted alkyl, aryl, or substituted aryl, and also refers to the salt thereof. The acyl radical bonds through the carbon atom.

The term “sulfite” refers to a radical of the formula —SO₃R, where R is hydrogen, alkyl, substituted alkyl, aryl, or substituted aryl, and also refers to the salt thereof. The acyl radical bonds through the carbon atom.

The term “β-dicarbonyl” refers to a radical of the formula —CO—CR¹R²—CO—R³ where R¹, R², and R³ are independently hydrogen, alkyl, substituted alkyl, aryl, or substituted aryl, and also refers to the salt thereof.

The term “imide” refers to a radical of the formula —CO—NR¹—CO—R², where R¹ and R² are independently hydrogen, alkyl, substituted alkyl, aryl, or substituted aryl, and also refers to the salt thereof.

The term “sulfonamide” refers to a radical of the formula —SO₂—NR¹R², where R¹ and R² are independently hydrogen, alkyl, substituted alkyl, aryl, or substituted aryl, and also refers to the salt thereof.

The term “sulfonyl” refers to a radical of the formula —SO₂—R, where R is hydrogen or alkyl.

The term “sulfonylurea” refers to a radical of either the formula —SO₂—NR¹—CO—NR²R³ or the formula —NR¹—CO—NR²—SO₂R³, where R¹, R², and R³ are independently hydrogen, alkyl, substituted alkyl, aryl, or substituted aryl, and also refers to the salt thereof.

The term “tetrazole” refers to a radical of the formula —CHN₄, which is heterocyclic.

The term “phosphate” refers to a radical of the formula —PO₄³⁻.

The term “phosphonate” refers to a radical of the formula —PO(OR)₂, where each R is independently hydrogen, alkyl, substituted alkyl, aryl, or substituted aryl, and also refers to the salt thereof.

The term “sulfate” refers to a radical of the formula —SO₄²⁻.

The term “substituted” refers to at least one hydrogen atom on the named radical being substituted with another functional group. An exemplary substituted alkyl group is a perhaloalkyl group, wherein one or more hydrogen atoms in an alkyl group are replaced with halogen atoms. An alkyl group can be substituted with a hydroxyl or halogen group. An aryl or heteroaryl group can be substituted with an alkyl, substituted alkyl, hydroxyl, and/or halogen group.

The term “up to X” is used in this disclosure to indicate an amount of a given material. This term should be construed to require the given material to be present in an amount greater than zero, or in other words to exclude the value zero.

The present disclosure refers to the pKa of various components. The pKa is measured according to known methods in a water system.

The present disclosure relates to photoresist compositions and methods for using such compositions in photolithographic processes for manufacturing integrated circuits/semiconductor devices. In this regard, photoresist compositions are coated onto a substrate, for example by spin-coating, and may also be cured by baking. The photoresist contains a photosensitive material. A patterned mask is used to cover portions of the photoresist and to expose portions of the photoresist to radiation, such as ultraviolet light or an electron beam. The photoresist is then developed using a chemical solution (known as developer). The developer removes portions of the photoresist (i.e. exposed portions in a positive-tone photoresist or unexposed portions in a negative-tone photoresist), so that the mask pattern is transferred to the photoresist layer. The patterned photoresist layer can then be used as an etch mask for subsequent etching processes that transfer the pattern to an underlying material layer.

The minimum feature size of the pattern may be affected by the light wavelength. Deep ultraviolet (UV) lithography uses a wavelength of 193 nm or 248 nm. Extreme ultraviolet (EUV) light, which spans wavelengths from 124 nanometers (nm) down to 10 nm, is currently being used to provide small minimum feature sizes. At such wavelengths, the photosensitive materials need to use the light as efficiently as possible. The efficiency of the photoresist can be increased using chemical amplification. In a chemically amplified resist or CAR, the photoresist composition includes a photosensitive polymer, a photoacid generator (PAG), and a quencher. Upon exposure to radiation, the PAG generates an acid. The acid cleaves an acid labile group (ALG) on the polymer to change the solubility of the polymer. This also produces an acid, which can continue the reaction. Such a chain reaction will be terminated only when the acid produced comes in contact with a base, also referred to as a quencher. The balance between the acids and the quencher determines the fidelity of the photoresist pattern, e.g. whether the sidewalls are straight or not.

The photoresist compositions of the present disclosure include an organic polymer (or resin) and a floatable polymer which has a lower surface energy than the organic polymer. Because of this difference in surface energy, upon deposition and curing, the organic polymer and the floatable polymer will spontaneously separate into two different layers. The organic polymer forms a photoresist layer and the floatable polymer “rises” to form a surface layer upon the photoresist layer. The surface layer can absorb out-of-band (OOB) radiation, reducing optical flare (i.e. unwanted light arriving on the substrate) which can result in enlarged trench critical dimension (CD) and reduced line CD in a positive tone development (PTD) process. The surface layer can also reduce or prevent outgassing, which in turn reduces chemical flare that can result in positive tone development (PTD) and/or scum in the exposed area. The photoresist compositions may further include a photoacid generator (PAG), a quencher, and a solvent.

The floatable polymer has a lower surface energy than the organic polymer that forms the photoresist layer. The surface energy of each polymer can be measured by their contact angle using methods known in the art. In particular embodiments, the contact angle of the floatable polymer is from about 75 degrees (°) to about 90°. For comparison, the contact angle of the organic polymer is usually from about 60° to about 75°.

The floatable polymer may be a homopolymer or a copolymer derived from two or more monomers. The floatable polymer contains a backbone with pendant groups or sidechains extending therefrom. The backbone of the floatable polymer is typically a hydrocarbon chain, for example formed from the polymerization of vinyl groups present in the monomers forming the floatable polymer. However, other backbone structures for the floatable polymer are contemplated. For example, the floatable polymer could have a polyester, a polycarbonate, or a polyamide backbone as well. As to stereochemistry, the floatable polymer may be isotactic, atactic, or syndiotactic.

Generally, to reduce the surface energy of the floatable polymer relative to the organic polymer, the floatable polymer contains fluorine atoms. The reduction in surface energy is usually proportional to the number of fluorine atoms in the floatable polymer.

In some specific embodiments of the present disclosure, the floatable polymer is a homopolymer having the general structure illustrated in Formula (I) below:

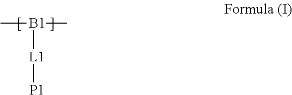

where the monomer is made up of parts B1, L1, and P1, where B1 forms part of the backbone; L1 is a linking group, and P1 is a pendant group. In particular embodiments, at least five (5) fluorine atoms are present in the monomer of the homopolymer. Up to 12 fluorine atoms may be present. In additional embodiments, the pKa of the monomer is less than 13.

In some particular embodiments, B1 is of the general formula (B-1):

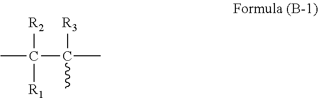

where R₁, R₂, and R₃ are independently hydrogen, alkyl, or alkyl substituted with fluorine atoms; and the wavy line indicates the connection to the linking group L1. In more specific embodiments contemplated herein, R₁, R₂, and R₃ are hydrogen.

In particular embodiments, the linking group L1 may be alkyl, which may be substituted with fluorine; alkoxy, which may be substituted with fluorine; cycloalkyl, which may be substituted with fluorine; aryl, which may be substituted with fluorine; heteroaryl, which may be substituted with fluorine; ester; sulfonyl; or —O—. In more specific embodiments, L1 is cycloalkyl; aryl; ester; or —O—. Particular examples of L1 may include phenyl (—C₆H₄—) or cyclohexyl (—C₆H₁₀—).

The pendant group P1 may be alkyl or substituted alkyl; carboxyl; hydroxyl; aryl or substituted aryl; or amino. Particular examples of P1 include —CH(CF₃)(CF₂OH); —C(CF₃)₂OH; —CH₂CH(CF₃)(CF₂OH); —COOH; or —OH. The pendant group P1 can be a fluoroalcohol group. In particular embodiments, the pendant group P1 contains at most four carbon atoms.

It is noted that in the event of any ambiguity of the structure of a particular monomer, the structure should be interpreted so that B1, L1, and P1 are all present. For example, 4-vinylbiphenyl should be interpreted as B1=vinyl; L1=phenyl (—C₆H₄); and P1=phenyl (—C₆H₅)

In other particular embodiments of the present disclosure, the floatable polymer is a copolymer which can be formed from two, three, four, five, or more different monomers. When the floatable polymer is a copolymer, it is usually a random copolymer.

Some particular copolymer embodiments of the floatable polymer are illustrated in Formulas (II) and (III) below:

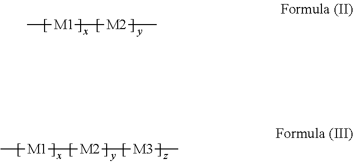

wherein M1, M2, and M3 are respectively different repeating units/monomers; wherein x is the molar ratio of monomer M1; y is the molar ratio of monomer M2; and z is the molar ratio of monomer M3; and
wherein x+y=1 in Formula (II); and x+y+z=1 in Formula (III).

Monomer M1 may be considered a first monomer type, monomer M2 may be considered a second monomer type, and monomer M3 may be considered a third monomer type. Each monomer type is different from the other monomer types, and thus the copolymers of Formulas (II) and (III) are also different from each other. All three monomer types contain parts B1, L1, and P1 as described with respect to Formula (I) above. However, although the copolymer itself contains fluorine atoms, not all monomers M1-M3 must contain fluorine atoms. In particular embodiments, when considering the monomers of the copolymer together, at least five (5) fluorine atoms are present in the monomers (regardless of the relative molar amounts of each monomer). Up to 12 fluorine atoms may be present in the monomers. It should be noted that while a particular monomer may fall within the definition of more than one of the monomers M1, M2, and M3 (as will be discussed below), Formulas (II) and (III) should be construed as requiring the presence of different monomers.

In particular embodiments of Formulas (II) and (III), x is about 0.20 to about 0.80, or in other words the copolymer contains from about 20 mole % to about 80 mole % of monomer M1. In some more specific monomers, x is 0.30 or greater. However, other values and ranges are also within the scope of this disclosure.

In particular embodiments of Formulas (II) and (III), y is about 0.20 to about 0.80, or in other words the copolymer contains from about 20 mole % to about 80 mole % of monomer M2. However, other values and ranges are also within the scope of this disclosure.

In particular embodiments of Formula (II) and (III), z is up to about 0.50, or in other words the copolymer contains up to about 50 mole % of monomer M3. However, other values and ranges are also within the scope of this disclosure.

Referring now to monomer type M1, this monomer type contains fluorine atoms and has a pKa of less than 13. In particular embodiments, the monomer type M1 contains at least five fluorine atoms, and more particularly may contain from 5 to about 12 fluorine atoms. The fluorine atoms are usually present in the pendant group P1, but could also be present in the backbone portion B1 or the linking group L1. The monomer type M1 should also be soluble in the developer that will be used to develop the photoresist. Some specific examples of pendant groups P1 suitable for monomer type M1 include substituted alkyl (usually substituted with fluorine). Particular examples of P1 for monomer type M1 include fluoroalcohol groups such as the —CH(CF₃)(CF₂OH); —C(CF₃)₂OH; and —CH₂CH(CF₃)(CF₂OH) pendant groups. In particular embodiments of monomer type M1, the pendant group P1 contains at most four carbon atoms. For reference, it is noted that the pKa of trifluoromethanol (CF₃OH) is 2.42; the pKa of nonafluoro-t-butyl alcohol (C₄F₉OH) is 5.4; and the pKa of trifluoroethanol (CF₃CH₂OH) is 12.5.

Some illustrative examples of repeating units/monomers M1 are shown below as Formulas (M1-a) through (M1-c):

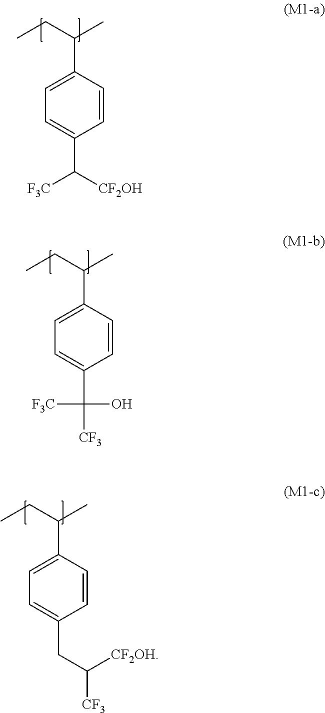

Referring now to monomer type M2, this monomer type also has a pKa of less than 13. In addition, this monomer type includes a functional group that is soluble in the solvent of the photoresist composition. The monomer type M2 should also be soluble in the developer that will be used to develop the photoresist. The monomer type M2 may contain fluorine atoms if desired. it is noted that the combination of monomer types M1 and M2 cause the surface layer to act as a top coat that prevents outgassing of the quencher from the photoresist layer. Some specific examples of pendant groups P1 suitable for monomer type M2 include fluoroalcohol, carboxyl, hydroxyl, β-dicarbonyl, imide, sulfonamide, sulfonylurea, tetrazole, sulfhydryl, phosphate, phosphonate, and sulfate. Some illustrative examples of repeating units/monomers M2 are shown below as Formulas (M2-a) and (M2-b):

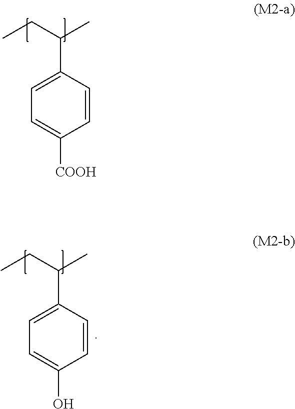

Referring now to monomer type M3, the monomer M3 may have several different functional groups suitable for various applications. For example, the monomer M3 may absorb UV wavelengths (i.e. act as a chromophore), act as a quencher, improve etch resistance or lower the etch rate, reduce rounding of the photoresist layer, contain a photoacid generator (PAG) group, or reduce developer swelling. Monomer type M3 encompasses many monomer sub-types, and one or more M3 sub-types may be present in the floatable copolymer.

One monomer sub-type is labeled herein as M3-I, and this monomer sub-type absorbs UV wavelengths, especially those between 100 nanometers (nm) and 400 nm. The monomer sub-type M3-I comprises at least one aromatic ring. In particular embodiments, the monomer sub-type M3-I has a total of from one to five aromatic rings (in L1 and P1). The monomer sub-type M3-I may also contain fluorine atoms if desired. Some specific examples of pendant groups P1 suitable for monomer sub-type M3-I include phenyl, naphthyl; phenanthryl; furyl; pyridyl; and derivatives thereof. In addition, these pendant groups can be substituted with electron donating groups such as amino, hydroxyl, alkoxy, alkyl, alkylthio, sulfhydryl, acylamido, and acyloxy; and/or with electron withdrawing groups such as nitro, cyano, halogen, nitroso, and acyl. Some illustrative examples of repeating units/monomers M3-I are shown below as Formulas (M3-a) through (M3-f):

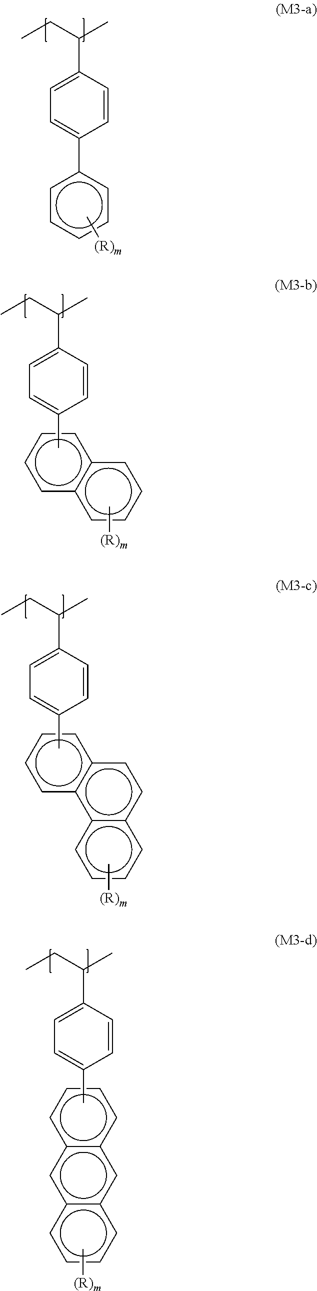

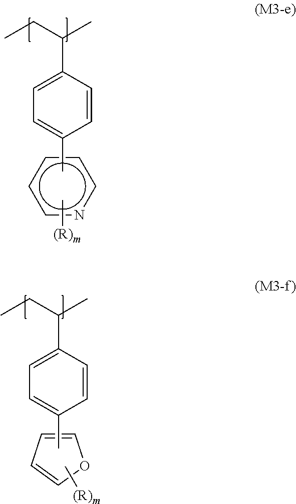

wherein R is an electron donating group or an electron withdrawing group as described above; and wherein m is 0 to 5.

It is noted that Formula (M3-b) should be considered to have a total of three aromatic rings, not only two aromatic rings, because the naphthyl group itself has two aromatic rings and should not be considered to be only one aromatic ring.

Referring now to monomer sub-type M3-II, this monomer sub-type contains a functional group that has a pKa higher than the pKa of the acid generated by the photoacid generator (PAG) of the photoresist composition. PAGs typically generate an acid with a pKa of less than 1. The monomer sub-type M3-II can be considered to act as a quencher that neutralizes acid at the surface of the exposed area of the photoresist layer. This reduces the acid concentration at the surface, which reduces or prevents rounding at the surface of the photoresist layer. In other embodiments, the monomer sub-type M3-II has a functional group with a pKa of greater than −10. When the functional group is ionic, the pKa of the conjugate acid should be used. Some specific examples of pendant groups P1 suitable for monomer sub-type M3-II include amino, carboxyl, and sulfite. phenyl, naphthyl; phenanthryl; furyl; pyridyl; and derivatives thereof. In other embodiments, the pendant group P1 includes a nitrogen atom having an unpaired electron capable of neutralizing an acid. Some illustrative examples of repeating units/monomers M3-II are shown below as Formulas (M3-g) through (M3-j):

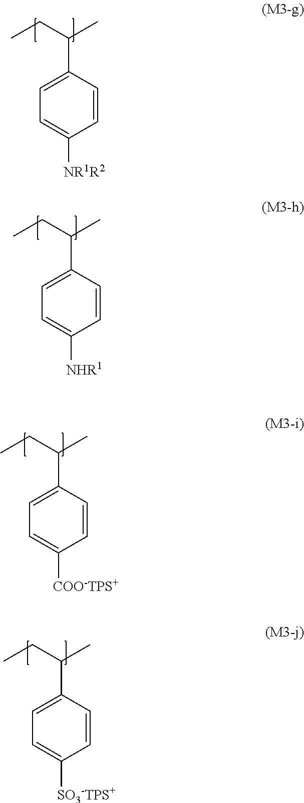

wherein R¹ and R² are as defined above for the amino radical, and TPS is the triphenylsulfonium cation.

Next, monomer sub-types M3-III and M3-IV are always used together. They improve the etch resistance of the floatable polymer and the resulting surface layer, and also reduce rounding of the photoresist layer. In particular embodiments, the molar ratio of monomer M3-III to M3-IV is from about 2:1 to about 1:2.

Monomer sub-type M3-III contains an acid labile group (ALG), which is cleaved upon exposure to acid. This cleavage causes the floatable polymer to become more hydrophilic. ALGs are well known in the art. The monomer sub-type M3-III thus provides for chemical amplification. In some particular embodiments, the ALG contains an inorganic atom, such as silicon, phosphorus, or sulfur. Some specific examples of pendant groups P1 suitable for monomer sub-type M3-III are illustrated in the non-limiting examples of repeating units/monomers shown below as Formulas (M3-k) and (M3-I):

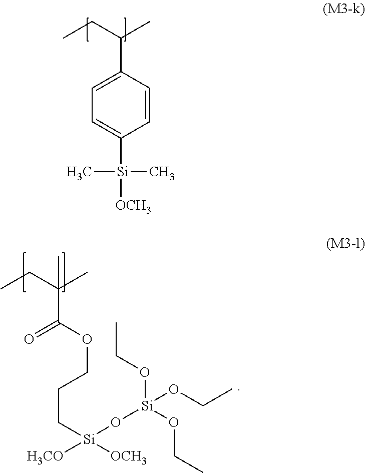

Monomer sub-type M3-IV contains a metal coordination complex having ligands and a metal atom. The metal atom can be any metal or transition metal atom, such as Ti, Fe, Sn, V, Cr, Co, Ni, Zn, Sb, Al, Pt, W, Zr, Mo, Pd, or Ag, among others. Some specific examples of pendant groups P1 suitable for monomer sub-type M3-IV are illustrated in the non-limiting examples of repeating units/monomers shown below as Formulas (M3-m) through (M3-o):

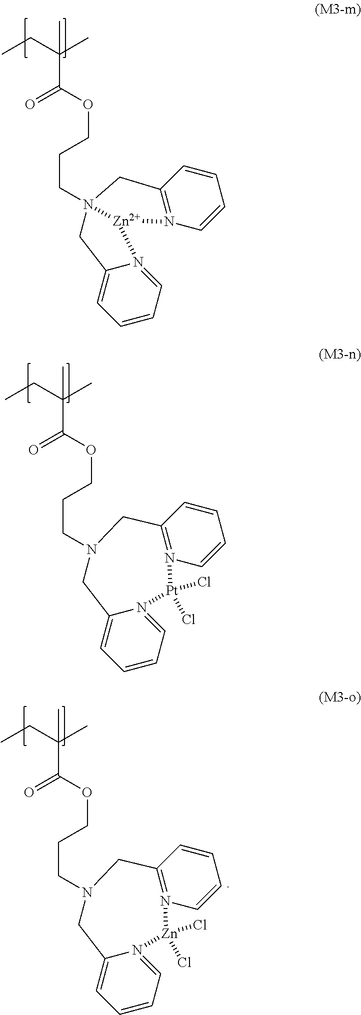

Continuing, monomer sub-type M3-V contains a photoacid generating (PAG) pendant group. In this monomer sub-type, the linking group L1 may also be a single bond. In some embodiments, the pendant group P1 includes a phenyl ring. In some embodiments, the PAG pendant group includes a halogenated triazine, onium salt, diazonium salt, aromatic diazonium salt, phosphonium salt, sulfonium salt, iodonium salt, imide sulfonate, oxime sulfonate, diazodisulfone, disulfone, o-nitrobenzylsulfonate, sulfonated ester, halogenated sulfonyloxy dicarboximide, diazodisulfone, α-cyanooxyamine-sulfonate, imidesulfonate, ketodiazosulfone, sulfonyldiazoester, 1,2-di(arylsulfonyl)hydrazine, nitrobenzyl ester, and/or s-triazine derivative. In some embodiments, the PAG pendant group includes a triarylsulfonium group, diaryliodonium group, trifluoromethanesulfonate group, or an iodonium sulfonate group.

Lastly, monomer sub-type M3-VI contains a pendant group which alleviates swelling in the developer, especially when the developer is an aqueous solvent like TMAH. One example of such a pendant group is a lactone.

As discussed above, more than one monomer M3 sub-type may be present in the copolymer at the same time. Referring back to Formula (III), when more than one sub-type is present, the sub-types are combined together to determine the molar ratio z. In some further embodiments, when more than one sub-type is present, each sub-type is present in the amount of at least 1 mole %.

The floatable polymers can be prepared from appropriate monomers using conventional polymerization techniques. Any suitable step-growth or chain-growth polymerization process may be used, such as addition polymerization, free radical polymerization, condensation polymerization, emulsion polymerization, solution polymerization, suspension polymerization, or precipitation polymerization.

The floatable polymer is one component of a photoresist composition. Other components of the photoresist composition include an organic polymer, a photoacid generator (PAG), a quencher, and a solvent. In particular embodiments, the floatable polymer is up to 50 wt % of the photoresist composition. Other optional additives may also be present in the photoresist composition, such as a surfactant, a sensitizer, a crosslinking agent, a stabilizer, a dissolution inhibitor, a plasticizer, a colorant, an adhesion promoter, and/or a surface leveling agent.

The organic polymer is, in particular embodiments, a positive-tone photoresist, which is photo-sensitive and is degraded by exposure to radiation. As a result, the developer will dissolve the regions that were exposed to light. Such positive-tone photoresists are well-known. In other embodiments contemplated herein, the organic polymer is a negative-tone photoresist. The floatable copolymer is compatible with both types of photoresist.

Non-limiting examples of PAGs may include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of PAGs include α-(trifluoromethylsulfonyloxy)-bicyclo[2.2.1]hept-5-ene-2,3-dicarboximide (MDT); N-hydroxy-naphthalimide (DDSN); benzoin tosylate; t-butylphenyl-α-(p-toluenesulfonyloxy)-acetate; t-butyl-α-(p-toluenesulfonyloxy)-acetate; triarylsulfonium and diaryliodonium hexafluoroantimonates; hexafluoroarsenates; trifluoromethanesulfonates; iodonium perfluorooctanesulfonate; N-camphorsulfonyloxynaphthalimide; N-pentafluorophenylsulfonyloxynaphthalimide; ionic iodonium sulfonates such as diaryl iodonium (alkyl or aryl)sulfonate and bis-(di-t-butylphenyl)iodonium camphanylsulfonate; perfluoroalkanesulfonates such as perfluoropentanesulfonate, perfluorooctanesulfonate, or perfluoromethanesulfonate; aryl triflates such as triphenylsulfonium triflate or bis-(t-butylphenyl)iodonium triflate; pyrogallol derivatives (e.g., trimesylate of pyrogallol); trifluoromethanesulfonate esters of hydroxyimides; α,α′-bis-sulfonyl-diazomethanes; sulfonate esters of nitro-substituted benzyl alcohols; naphthoquinone-4-diazides; ethanone; and alkyl disulfones.

A quencher can be used to inhibit diffusion of the generated acid within the photoresist, which improves the stability of the photoresist and also improves the resist pattern configuration. Non-limiting examples of quenchers include amines and organic acids. The amine may be a second lower aliphatic amine or a tertiary lower aliphatic amine. Specific examples of amine quenchers include trimethylamine; diethylamine; triethylamine; di-n-propylamine; tri-n-propylamine; tripentylamine; diethanolamine; triethanolamine; and other alkanolamine.

Examples of organic acids that can be used as quenchers may include malonic acid; citric acid; malic acid; succinic acid; benzoic acid; salicylic acid; phosphoric acid and derivatives thereof such as phosphoric acid di-n-butyl ester or phosphoric acid diphenyl ester; phosphonic acid and derivatives thereof such as phosphonic acid dimethyl ester, phosphonic acid di-n-butyl ester; phenylphosphonic acid, phosphonic acid diphenyl ester, or phosphonic acid dibenzyl ester; and phosphinic acid and derivatives thereof such as its esters or phenylphosphinic acid.

The various components are mixed or blended together in a solvent to form the photoresist composition. In particular embodiments, the solvent is an organic solvent. Examples of suitable organic solvents include propylene glycol monomethyl ether (PGME), propylene glycol methyl ether acetate (PGMEA), and mixtures of PGME and PGMEA commercially known as OK73. Other examples include ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

A surfactant may be present in the photoresist composition. Upon development, the surfactant may facilitate the removal of residues from the photoresist layer. The surfactant may be an alkyl cationic surfactant, an amide-type quaternary cationic surfactant, an ester-type quaternary cationic surfactant, an amine oxide surfactant, a betaine surfactant, an alkoxylate surfactant, a fatty acid ester surfactant, an amide surfactant, an alcohol surfactant, an ethylenediamine surfactant, or a fluorine- and/or silicon-containing surfactant.

A sensitizer may be present in the photoresist composition. Upon irradiation, the sensitizer is designed to generate radiation of a different wavelength, such that the sensitivity of the photoresist material is substantially improved. In some embodiments, the sensitizer may include fluorine, a metal, or a phenol group. For example, the sensitizer may be polyhydroxystyrene (PHS) or polyfluorostyrene. Other sensitizers like organic iodides, bromides, chlorides, or magnesium-containing compounds which have a high electron-beam cross section could also be used.

A crosslinking agent may also be added to the photoresist composition. The cross-linking agent can react with the organic polymer after exposure, assisting in increasing the cross-linking density of the photoresist, which helps to improve the resist pattern and resistance to etching. Examples of cross-linking agents can include melamines, ureas, glycoluril compounds, aliphatic hydrocarbons having hydroxyl or thiol or hydroxyalkyl groups, alcohols, and etherified amino resins.

A stabilizer may be included in the photoresist composition. The stabilizer reduces diffusion of the acids generated during exposure of the photoresist composition. Examples of stabilizers include nitrogenous compounds such as aliphatic primary, secondary, and tertiary amines; cyclic amines such as piperidines, pyrrolidines, and morpholines; aromatic heterocycles such as pyridines, pyrimidines, and purines; imines; guanidines; imides; amides; ammonium salts; cationic nitrogenous compounds; phenolates; carboxylates; aryl and alkyl sulfonates; sulfonamides; and the like.

A dissolution inhibitor may be included in the photoresist composition to help control dissolution of the photoresist during development. Non-limiting examples of dissolution inhibitors include cholic acid, deoxycholic acid, lithocholic acid, t-butyl deoxycholate, t-butyl lithocholate, and t-butyl-3-α-acetyl lithocholate.

A plasticizer may be used in the photoresist composition to reduce delamination and cracking between the photoresist and the underlying layer upon which the photoresist layer is formed. Examples of plasticizers may include monomeric, oligomeric, and polymeric plasticizers such as oligo- and polyethyleneglycol ethers, cycloaliphatic esters, and non-acid reactive steroidally-derived materials. Specific examples of materials that may be used for the plasticizer include dioctyl phthalate, didodecyl phthalate, triethylene glycol dicaprylate, dimethyl glycol phthalate, tricresyl phosphate, dioctyl adipate, dibutyl sebacate, triacetyl glycerine, and the like.

If desired, a colorant could be used to help in locating defects in the photoresist. Broad categories of colorants include dyes and pigments. More specific examples of colorants may include triarylmethane dyes, crystal violet, methyl violet, ethyl violet, malachite green, diamond green, phthalocyanine pigments, azo pigments, carbon black, titanium oxide, benzophenone compounds; salicylic acid compounds; phenylacrylate compounds; coumarin compounds; thioxanthone compounds; stilbene compounds; naphthalic acid compounds; azo dyes; and the like.

An adhesion promoter may be used in the photoresist composition to promote adhesion between the photoresist and the underlying layer upon which the photoresist layer is formed. Examples of adhesion promoters include silane compounds with at least one reactive substituent such as a carboxyl group, a methacryloyl group, an isocyanate group and/or an epoxy group.

Surface leveling agents may additionally be added to the photoresist composition, for leveling the top surface of the photoresist layer. Examples of surface leveling agents include fluoroaliphatic esters, hydroxyl terminated fluorinated polyethers, fluorinated ethylene glycol polymers, silicones, and acrylic polymer leveling agents.

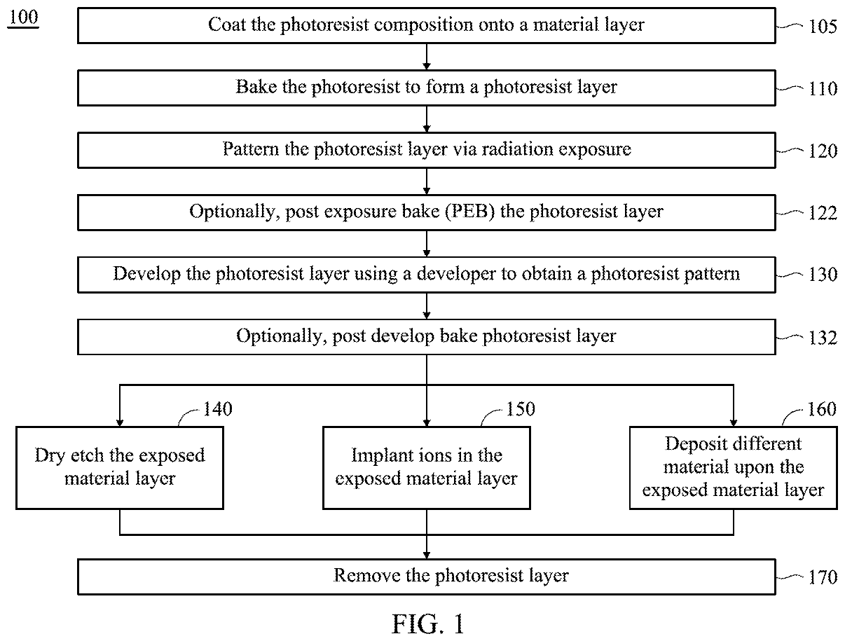

The photoresist composition is used to form a photoresist layer that is used in various methods for forming various structures in an integrated circuit or semiconductor device. One such method 100 for forming a photoresist pattern and patterning a material layer in a semiconductor device is described in FIG. 1.

Initially, it may be desirable to heat the substrate prior to beginning the photoresist patterning process. This may improve resist adhesion by desorbing water present on the substrate surface and to thermally crack any hydroxide bonds present on an oxidized surface. The substrate can be heated to temperatures above 100° C. up to, for example, 200° C. for a period of several minutes. The substrate is then cooled back down to room temperature.

In step 105, the photoresist composition is coated onto a substrate. It is noted that the substrate may be any type of material layer in which a pattern is desired to be formed. The coating may be done, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

In step 110, the photoresist composition is baked or cured to remove the solvent and harden the photoresist layer. In some particular embodiments, the baking occurs at a temperature of about 80° C. to about 130° C., and for a time period of about 60 seconds. The baking can be performed using a hot plate or oven, or similar equipment.

As a result of these steps, the floatable polymer “floats” to the top of the photoresist composition. The photoresist layer is formed on the substrate, and the floatable polymer forms a surface layer on top of the photoresist layer.

In step 120, the photoresist layer is patterned via exposure to radiation. The radiation may be any light wavelength which carries a desired mask pattern, although ultraviolet (“UV”) radiation is typically used at the current time. UV radiation has a wavelength in the range of about 10 nanometers (“nm”) to about 400 nm, such as from KrF lasers (248 nm) or ArF lasers (193 nm). In particular embodiments, extreme ultraviolet (“EUV”) light having a wavelength of about 13.5 nm is used for patterning, as this permits smaller feature sizes to be obtained. In other embodiments, e-beam radiation is used. This results in some portions of the photoresist layer being exposed to radiation, and some portions of the photoresist not being exposed to radiation. This exposure activates the organic polymer, such that some portions of the photoresist will be soluble in the developer and some portions of the photoresist will not be soluble in the developer.

In optional step 122, an additional photoresist bake step (post exposure bake, or PEB) may occur after the exposure to radiation. This may help in releasing the acid labile groups (ALGs) or other molecules that are significant in chemical amplification.

In step 130, the photoresist layer is developed using a developer. The developer may be an aqueous solution or an organic solution. The soluble portions of the photoresist layer are dissolved and washed away during the development step, leaving behind a photoresist pattern. There are two types of development processes, positive tone development (PTD) and negative tone development (NTD). PTD generally uses a developer that selectively dissolves and removes exposed portions of the photoresist layer. NTD process uses a developer that selectively dissolves and removes unexposed portions of the photoresist layer. In some embodiments, the PTD developers are aqueous base developers, such as tetramethylammonium hydroxide (TMAH). In some embodiments, the NTD developers are organic-based developers, such as n-butyl acetate (n-BA), iso-amyl acetate(IAA) or other solvent that can dissolve unexposed portions of the resist layer Generally, any suitable developer may be used.

In optional step 132, a post develop bake or “hard bake” may be performed to stabilize the photoresist pattern, for optimum performance in subsequent steps.

Continuing, portions of the material layer below the photoresist pattern are now exposed. In step 140, the material layer is etched, causing the exposed portions of the material layer to be removed, thus transferring the photoresist pattern to the material layer. In particular embodiments, the etching is performed by dry etching.

Besides etching of the material layer, other process steps may alternatively be carried out. For example, in alternative step 150, ions may be implanted into the exposed material layer instead, or as in alternative step 160, a different material can be deposited upon the material layer.

Finally, in step 170, the photoresist layer can then be removed. This can be done, for example, using various solvents such as N-methyl-pyrrolidone (NMP) or alkaline media or other strippers at elevated temperatures, or by dry etching using oxygen plasma.

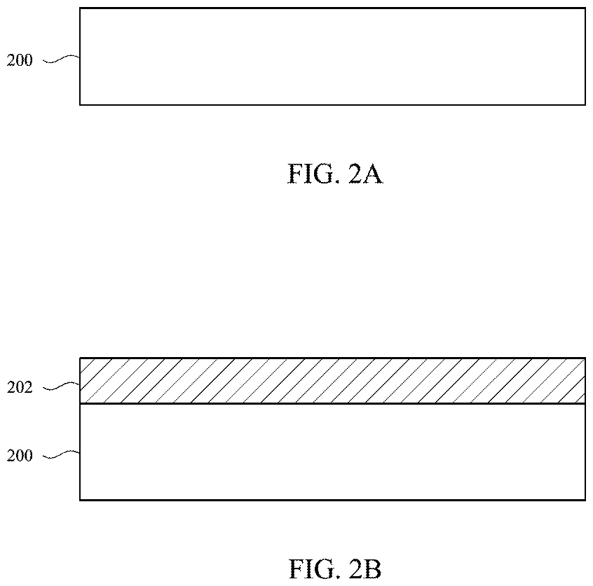

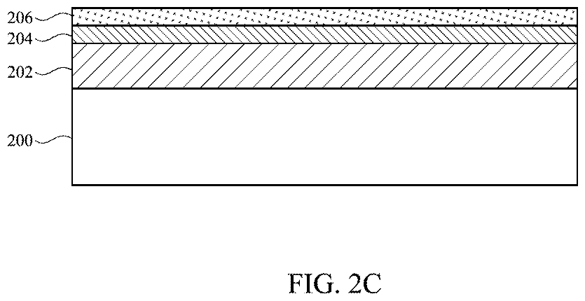

FIGS. 2A-6 illustrate various aspects of the method of FIG. 1. These figures provide different views for better understanding.

Referring first to FIG. 2A, this figure shows one example of the beginning state of the substrate 200 prior to any processing steps. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon. As illustrated here, no additional layers are present upon the substrate 200.

In contrast, in FIG. 2B, a first material layer 202 is present upon the substrate 200. The first material layer may be any material that may be used in a semiconducting device or integrated circuit. For example, the first material layer could be made of an insulating material, such as silicon dioxide (SiO₂) or silicon nitride (SiN), silicon oxynitride (SiON), fluoride-doped silicate glass, or other dielectric material. As another example, the first material layer could be made of an electrically conductive material, such as polysilicon or a metal like aluminum, copper, titanium, or tungsten. The first material layer may generally serve any function. For example, the first material layer could be a high-k dielectric layer, a gate layer, a hard mask layer, an interfacial layer, a capping layer, a diffusion/barrier layer, a dielectric layer (e.g. SiO₂), a conductive layer (e.g. doped polysilicon), or some other layer. The figures below show a first material layer being present, for illustrative purposes only and with it being understood that the substrate can also be etched.

In FIG. 2C, one or more underlayers have been applied to the substrate prior to the photoresist composition being applied. In this regard, the term “underlayer” is relative to the photoresist layer, and refers to any layers which may be applied to the layer that is desired to be etched prior to applying the photoresist composition. Put another way, any layers between the layer to be etched and the photoresist layer can be considered an underlayer. In this illustration, two underlayers 204, 206 are applied upon the first material layer 202.

As one example, the lower underlayer 204 may be a bottom anti-reflective coating (BARC). When a photoresist layer is applied to a reflective substrate, light reflection from the substrate/resist interface can create variations in light exposure, that cause problems with critical dimension (CD) control. For example, light can reflect into areas where exposure was not intended, changing the desired pattern. A BARC can be applied between the substrate and the photoresist layer to minimize or eliminate such problems. Examples of suitable BARCs include amorphous carbon and various organic polymers. The BARC layer is typically formed by spin coating, though other methods can also be used. The BARC coating or film is then baked or cured to induce crosslinking and solvent removal, and hardening of the BARC. In some particular embodiments, the baking occurs at a temperature of about 125° C. to about 275° C. In particular embodiments, the baking takes place for a time of about 30 seconds to about 250 seconds. The baking can be performed using a hot plate or similar equipment.

As another example, the upper underlayer 206 may be a hard mask layer. The hard mask layer may be formed from a dielectric material, a metal, or other suitable material. Examples of suitable dielectric materials may include silicon carbide, silicon nitride, silicon oxycarbide, or silicon oxynitride. The hard mask layer may be formed by any suitable process such as chemical vapor deposition (CVD), low-pressure CVD (LPCVD), plasma-enhanced CVD (PECVD), physical vapor deposition (PVD), atomic layer deposition (ALD), or spin coating. The BARC layer and the hard mask layer are also typically selected to have significantly different etching sensitivity towards the same etchant. Combined with the photoresist layer, this multi-layer resist pattern can also help improve line width roughness (LWR).

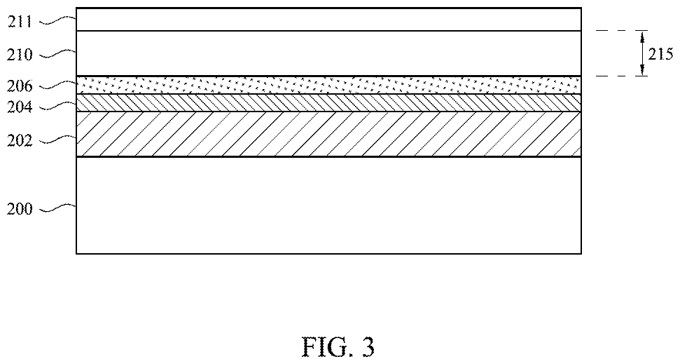

Now, beginning with step 105 of FIG. 1 and as illustrated in FIG. 3, the photoresist composition is applied over the substrate, and onto a material layer such as underlayer 206. The photoresist composition may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist composition evenly from the center of the substrate to the perimeter of the substrate. The rotating speed of the platen is then fixed, which can control the thickness of the final photoresist layer. Referring to FIG. 3, after the coating is performed, the photoresist composition separates into the photoresist layer 210 and the surface layer 211. The photoresist layer 210 may have a thickness 215 of about 10 nanometers to about 100 nanometers.

Next, in step 110 of FIG. 1 and referring still to FIG. 3, the photoresist composition is prebaked to remove the solvent and harden the photoresist layer and the surface layer. This may also be referred to as a softbake. In some particular embodiments, the prebake occurs at a temperature of about 40° C. to about 130° C., including from about 250° C. to about 800° C. or from about 80° C. to about 130° C. The time for the prebake may depend upon the thickness of the photoresist layer and the surface layer, with longer times for greater thicknesses, and in particular embodiments from about 10 seconds to about 10 minutes. The baking can be performed using a hot plate or oven, or similar equipment. The substrate and the other layers thereon are then cooled down to room temperature.

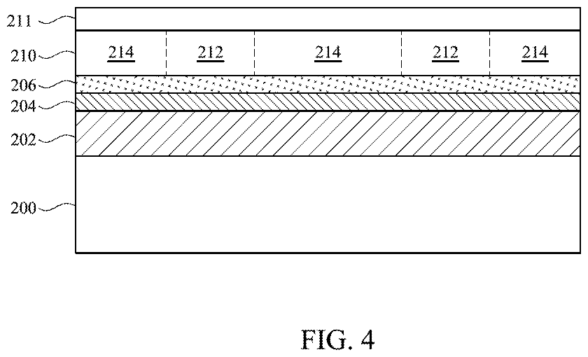

Continuing, in step 120 of FIG. 1, the photoresist layer 210 is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. In other embodiments, electron-beam (e-beam) radiation is used. Electron beams can be characterized by the energy of the beam, which in some embodiments ranges from about 5 kilovolts (kV) to about 200 kV. This step results in some portions of the photoresist layer being exposed to radiation, and some portions of the photoresist not being exposed to radiation. This exposure causes some portions of the photoresist to remain soluble in the developer and other portions of the photoresist to become insoluble in the developer. Referring now to FIG. 4, the photoresist layer 210 now includes soluble regions 212 and insoluble regions 214. It is noted for reference that EUV and e-beam radiation exposure typically occur under vacuum. The surface layer 211 may or may not be affected by the radiation exposure in the same manner as the photoresist layer.

Optionally, in step 122 of FIG. 1, a post exposure bake (PEB) occurs after the exposure to radiation. The PEB step can be used to complete any cross-linking within the photoresist, or to complete any chemically amplified reactions that may occur. In addition, the PEB step may reduce mechanical stress that might build up during the prior steps. In some particular embodiments, the PEB occurs at a temperature of about 40° C. to about 250° C., including from about 100° C. to about 250° C. or from about 90° C. to about 150° C. The time for the PEB may range from about 10 seconds to about 10 minutes, and may vary depending on the thickness of the photoresist layer and the surface layer.

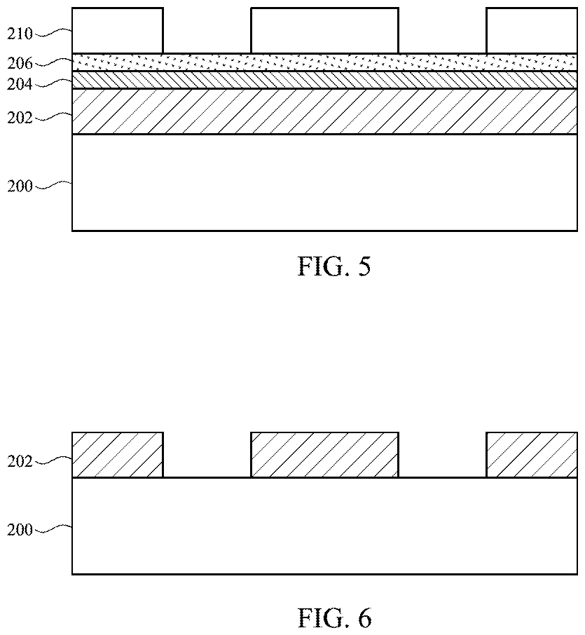

Next, in step 130 of FIG. 1, the photoresist layer 210 is developed using a developer. The developer may be applied by spin coating, spraying, or other suitable process. The soluble portions of the photoresist layer are dissolved and washed away during the development step, leaving behind a patterned photoresist layer. This may be done, for example, by spin drying. The resulting structure is illustrated in FIG. 5. As seen here, the soluble regions have been washed away, resulting in a patterned photoresist layer. In addition, the surface layer has also been washed away

In optional step 132 of FIG. 1, a post develop bake or “hardbake” may be performed after development. This can be done to stabilize the photoresist pattern after development, for optimum performance in subsequent steps. In some particular embodiments, the hardbake occurs at a temperature of about 100° C. to about 160° C. The time for the hardbake may range from about 1 minute to about 10 minutes, and may vary depending on the thickness of the photoresist layer.

Continuing, then, as seen in FIG. 5, portions of the upper underlayer 206, the lower underlayer 204, and the first material layer 202 below the patterned photoresist layer are now exposed.

Then, in step 140 of FIG. 1, etching is performed through the patterned photoresist layer to transfer the photoresist pattern through the underlayers 206, 204 to the first material layer 202 and obtain a patterned material layer. Desirably, each of the etchants for the various layers differs significantly from that of the other layers, which improves the LWR in the first material layer. It should be understood that the patterned material layer can be either the first material layer or the substrate as well. In some embodiments, the first material layer is an insulating layer, and the etched pattern may subsequently be filled with a conductive material to form a circuit within this insulating layer. In other alternate embodiments, the first material layer is a conductive layer, and the etched pattern is subsequently filled with an insulating material.

Generally, these etching steps may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Besides etching of the first material layer, other process steps may alternatively be carried out. For example, in alternative step 150, ions may be implanted into the exposed material layer instead, or as in alternative step 160, a different material can be deposited upon the material layer.

Next, in step 170 of FIG. 1, the patterned photoresist layer 210 is removed. The underlayers are also removed. The photoresist layer, the upper underlayer, and the lower underlayer can be removed using conventional means such as plasma stripping, solvent, or chemical-mechanical planarization (CMP). The resulting structure is illustrated in FIG. 6, with the first material layer 202 being patterned.

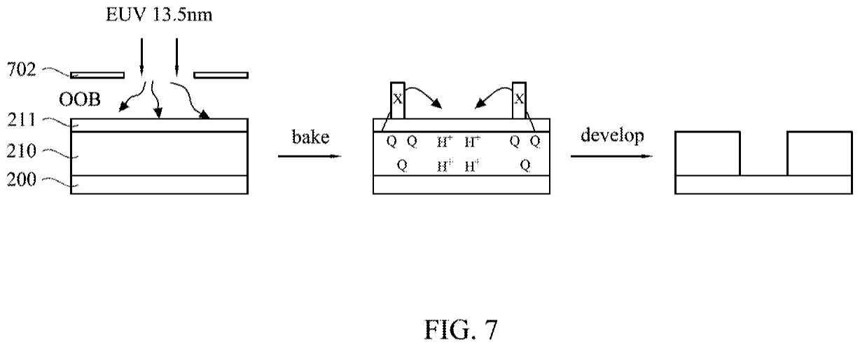

The addition of the floatable polymer to the photoresist composition provides many advantages. First, as illustrated in FIG. 7, the surface layer 211 covers the photoresist layer 210 upon the substrate 200 during exposure of radiation through the mask 702. The surface layer absorbs out-of-band (OOB) radiation, which reduces or prevents the curing of photoresist in masked and non-exposed areas which can otherwise occur. After post-exposure baking, the surface layer 211 also acts as a top coat and prevents component outgassing from the photoresist layer. This reduces chemical flare. The floatable polymer can also provide increased etch resistance and reduce top rounding of the photoresist layer. As a result, after development, there is no loss of critical dimension (CD) in the photoresist, CD variation is reduced in the photoresist, and the resulting features that are thus formed also maintain their CD.

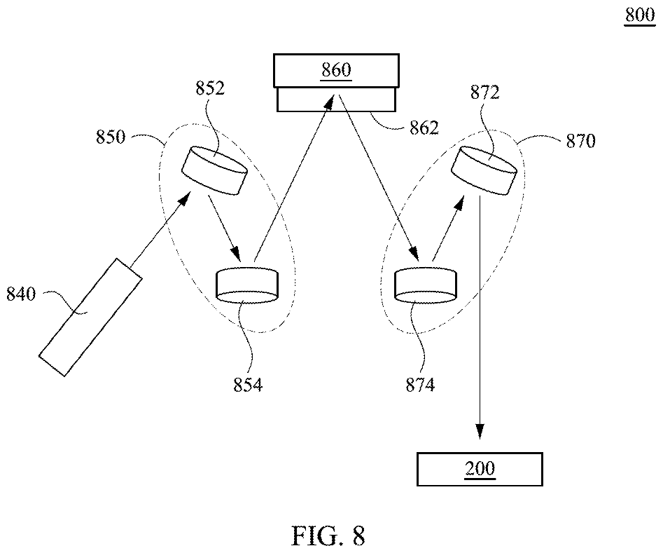

FIG. 8 is an illustrative schematic diagram, not drawn to scale, illustrating the various components of an extreme ultraviolet (EUV) photolithography system which generates the radiation to which the photoresist is exposed. Generally, the EUV photolithography system 800 begins with an EUV light source 840 that generates EUV light or radiation. Downstream of the EUV light source is an illumination stage 850 in which the EUV light may be collected and focused as a beam, for example using field facet mirror 852 that splits the beam into a plurality of light channels. These light channels can then directed using one or more relay mirrors 854 onto the plane of the photomask. The photomask 860 may include a pellicle membrane 862, through which the radiation passes before and/or after contacting the photomask. Downstream of the photomask 860 is the projection optics module 870, which is configured for imaging the pattern of the photomask onto the semiconductor wafer substrate 200. The projection optics module 870 may include refractive optics or reflective optics for carrying the image of the pattern defined by the photomask. Illustrative mirrors 872, 874 are shown. The lithography system can include other modules or be integrated with or coupled to other modules.

Additional processing steps may be performed to fabricate a semiconductor device or integrated circuit. Examples of such steps may include ion implantation, deposition of other materials, etching, etc.

Some aspects of the present disclosure thus relate to methods for forming a photoresist pattern. A substrate is coated with a photoresist composition that comprises an organic polymer and a floatable polymer. The floatable polymer has a lower surface energy than the organic polymer. The organic polymer forms a photoresist layer on the substrate and the floatable polymer forms a surface layer on the photoresist layer. The photoresist layer and the surface layer are then cured. The photoresist layer is patterned through exposure to radiation. The photoresist layer is then developed to form the photoresist pattern.

Other aspects of the present disclosure relate to methods for forming a patterned material layer. A substrate is coated with a photoresist composition that comprises an organic polymer and a floatable polymer. wherein the organic polymer forms a photoresist layer on the substrate and the floatable polymer forms a surface layer on the photoresist layer after the coating. The photoresist layer comprising the organic polymer and the surface layer over the photoresist layer comprising the floatable polymer are then cured. The photoresist layer is exposed to radiation to pattern the photoresist layer. Optionally, a post-exposure bake of the coated substrate is performed. The patterned photoresist layer is developed using a developer. Optionally, the patterned photoresist layer is hardbaked. Etching is then performed through the patterned photoresist layer to obtain a patterned material layer upon the substrate.

Also disclosed in various embodiments are photoresist compositions, comprising: an organic polymer; up to 50 wt % of a floatable polymer; a photoacid generator; a quencher; and a solvent. The floatable polymer has a lower surface energy than the organic polymer.

The methods and devices of the present disclosure are further illustrated in the following non-limiting working examples, it being understood that the examples are intended to be illustrative only and that the disclosure is not intended to be limited to the materials, conditions, process parameters and the like recited herein.

### EXAMPLES

Experiments were carried out to illustrate the effectiveness of using the floatable polymer in controlling the shape of the photoresist layer.

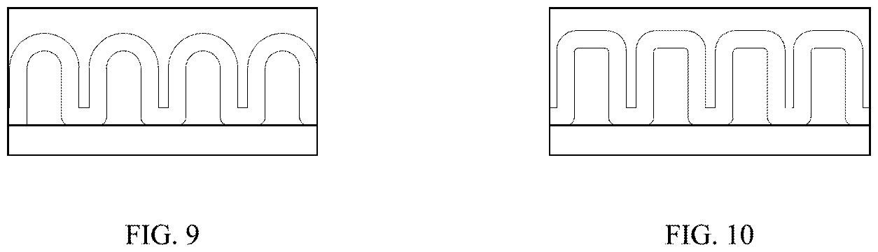

First, a photoresist composition with no floatable polymer was applied. Thus, no surface layer was present during development. FIG. 9 is an image showing the photoresist layer after development.

In a second experiment, a photoresist composition containing the floatable polymer was applied. Thus, a surface layer was present during development. FIG. 10 is an image showing the photoresist layer after development. As can be seen by comparing FIG. 9 and FIG. 10, the use of the floatable polymer resulted in the photoresist layer having a more square profile, with less rounding at the top.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a photoresist pattern, comprising:
coating a substrate with a photoresist composition comprising an organic polymer and a floatable polymer mixed with the organic polymer, wherein the organic polymer forms a photoresist layer on the substrate and the floatable polymer forms a surface layer on the photoresist layer after the coating; and
curing the photoresist layer and the surface layer;
patterning the photoresist layer through exposure to radiation; and
developing the photoresist layer to form the photoresist pattern.

2. The method of claim 1, wherein the floatable polymer has a lower surface energy than the organic polymer.

3. The method of claim 1, wherein the floatable polymer has a contact angle of about 75° to about 90° which is higher than the organic polymer.

4. The method of claim 1, wherein the floatable polymer comprises a first monomer (M1) and a second monomer (M2);
wherein the first monomer (M1) contains fluorine atoms and has a pKa of less than 13; and
wherein the second monomer (M2) is different from the first monomer (M1), and comprises a functional group that is soluble in a solvent of the photoresist composition, and has a pKa of less than 13.

5. The method of claim 4, wherein the first monomer (M1) comprises 5 or more fluorine atoms.

6. The method of claim 4, wherein the second monomer (M2) comprises a carboxylic acid group, a fluoroalcohol group, or a phenol group.

7. The method of claim 4, wherein the floatable polymer comprises 30 mole % or more of the first monomer (M1); or
wherein the floatable polymer comprises 20 mole % to 80 mole % of the second monomer (M2).

8. The method of claim 4, wherein the floatable polymer further comprises a third monomer (M3) that is different from the first monomer (M1) and the second monomer (M2);
wherein either the third monomer comprises at least one aromatic ring (M3-I); or
wherein the third monomer either contains a functional group with a pKa higher than a pKa of a photoacid generator (PAG) of the photoresist composition, or contains a functional group that has a pKa of greater than −10 (M3-II).

9. The method of claim 8, wherein the third monomer (M3) comprises up to 5 aromatic rings.

10. The method of claim 8, wherein the third monomer (M3) absorbs wavelengths between 100 nm and 400 nm.

11. The method of claim 8, wherein the floatable polymer comprises up to 50 mole % of the third monomer (M3).

12. The method of claim 8, wherein the third monomer (M4) comprises an —NR₂ group, a carboxyl group, or a sulfite group, wherein each R is independently hydrogen or alkyl.

13. The method of claim 4, wherein the floatable polymer further comprises a third monomer (M3-III) and a fourth monomer (M3-IV), wherein the third monomer (M3-III) comprises an acid labile group (ALG) and the fourth monomer (MIII-IV) comprises a metal coordination complex.

14. The method of claim 13, wherein the third monomer (M3-III) further comprises an inorganic atom.

15. The method of claim 13, wherein a mole ratio of the third monomer (M3-III) to the fourth monomer (M3-IV) is from about 2:1 to about 1:2.

16. The method of claim 4, wherein the floatable polymer further comprises a third monomer (M3) that contains a pendant photoacid generating (PAG) group or a pendant group that alleviates developer swelling.

17. A method for forming a patterned material layer, comprising:
coating a substrate with a photoresist composition comprising an organic polymer and a floatable polymer, wherein the organic polymer forms a photoresist layer on the substrate and the floatable polymer forms a surface layer on the photoresist layer after the coating;
curing the the organic polymer and the surface layer;
exposing the photoresist layer to radiation to pattern the photoresist layer;
optionally performing a post-exposure bake of the coated substrate;
developing the patterned photoresist layer using a developer;
optionally hard baking the patterned photoresist layer; and
etching through the patterned photoresist layer to obtain a patterned material layer upon the substrate.

18. The method of claim 17, wherein the floatable polymer is a random copolymer.

19. A photoresist composition, comprising:
an organic polymer;
up to 50 wt % of a floatable polymer;
a photoacid generator;
a quencher; and
a solvent;
wherein the floatable polymer has a lower surface energy than the organic polymer.

20. The photoresist composition of claim 19, wherein the floatable polymer comprises fluorine.
